(19) United States
(12) Patent Application Publication
(10) Pub. No.: US 2025/0311446 A1
(43) Pub. Date: Oct. 2, 2025

(54) Protection Circuit with a FET Device Coupled from a Protected Bus to Ground

(71) Applicant: Semtech Corporation, Camarillo, CA (US)

(72) Inventors: Lei Hua, Camarillo, CA (US); William Allen Russell, Thousand Oaks, CA (US); Changjun Huang, Oak Park, CA (US); Bo Liang, Shanghai (CN); Pengcheng Han, Shenzhen (CN)

(73) Assignee: Semtech Corporation, Camarillo, CA (US)

(21) Appl. No.: 19/236,145

(22) Filed: Jun. 12, 2025

Related U.S. Application Data
(63) Continuation of application No. 17/364,407, filed on Jun. 30, 2021, now Pat. No. 12,356,728.
Application No. 17/364,407 is a continuation of application No. 16/292,540, filed on Mar. 5, 2019, now Pat. No. 11,114,432.
(60) Provisional application No. 62/643,923, filed on Mar. 16, 2018.

(51) Int. Cl. H10D 89/60; H02H 9/04; H10D 10/00

(52) U.S. Cl. CPC H10D 89/814; H02H 9/041; H02H 9/046; H10D 89/713; H10D 89/819; H10D 10/00

(57) ABSTRACT

A semiconductor device includes a voltage input circuit node and a ground voltage node. A first transistor is coupled between the voltage input circuit node and the ground voltage node. A triggering circuit is coupled between the voltage input circuit node and the ground voltage node in parallel with the first transistor. The triggering circuit includes a trigger diode. An output of the triggering circuit is coupled to a control terminal of the first transistor. A load is powered by coupling the load between the voltage input circuit node and the ground voltage node.

### CLAIM OF DOMESTIC PRIORITY

The present application is a continuation of U.S. patent application Ser. No. 17/364,407, filed Jun. 30, 2021, which is a continuation of U.S. patent application Ser. No. 16/292,540, now U.S. Pat. No. 11,114,432, filed Mar. 5, 2019, which claims the benefit of U.S. Provisional Application No. 62/643,923, filed Mar. 16, 2018, which applications are incorporated herein by reference.

### FIELD OF THE INVENTION

The present invention relates in general to electrical overstress (EOS) and electrostatic discharge (ESD) protection circuits, and, more particularly, to a protection circuit that routes electrical current surges to ground through a transistor.

### BACKGROUND OF THE INVENTION

Semiconductor devices are commonly found in modern electronic products. Semiconductor devices vary in the number and density of electrical components. Discrete semiconductor devices generally contain one type of electrical component, e.g., a light emitting diode (LED), small signal transistor, resistor, capacitor, inductor, or power metal-oxide-semiconductor field-effect transistor (MOSFET). Integrated semiconductor devices typically contain hundreds to millions of electrical components. Examples of integrated semiconductor devices include microcontrollers, microprocessors, charged-coupled devices (CCDs), solar cells, and digital micro-mirror devices (DMDs).

Semiconductor devices perform a wide range of functions such as signal processing, high-speed calculations, transmitting and receiving electromagnetic signals, controlling electronic devices, transforming sunlight to electricity, and creating visual projections for television displays. Semiconductor devices are found in the fields of entertainment, communications, power conversion, networks, computers, and consumer products. Semiconductor devices are also found in military applications, aviation, automotive, industrial controllers, and office equipment.

Transient voltage suppression (TVS) diodes are commonly used to protect semiconductor devices from electrostatic discharge (ESD) and electrical overstress (EOS) events. A TVS diode can be provided with the cathode connected to a voltage input of the semiconductor device and the anode connected to a ground node to protect from voltage surges on the voltage input. A TVS diode is approximately an open circuit at normal voltage levels, but the resistance of electrical current through the TVS diode is significantly reduced when the input voltage potential exceeds a breakdown voltage (V_{BR}) of the TVS diode. Excess electrical current from ESD or EOS events flows through the TVS diode to the ground node, which helps keep the input voltage potential within safe levels for the attached load. The load can be an integrated circuit (IC), circuit board, another circuit element, any combination of circuit elements, or any other device being powered by the input voltage.

One problem with TVS diodes for ESD and EOS suppression is that TVS diodes absorb a large portion of the transient energy shunted to ground. Thus, a high-energy TVS must be physically large. The problem is compounded for high voltage systems, such as industrial sensors, automotive load dumps, and motor controllers. Because the maximum amount of energy a TVS diode can absorb is proportional to its size, applications with both high voltage input and high current transients may require an impractically large TVS diode. Therefore, a need exists for an improved protection device usable for high voltage and high transient current surge suppression applications.

### BRIEF DESCRIPTION OF THE DRAWINGS

FIG. 1 illustrates a field effect transistor (FET) coupled between a voltage line and ground for EOS suppression;

FIGS. 2a and 2b illustrate using TVS diodes as triggering circuits for the EOS FET;

FIGS. 3a and 3b illustrate bipolar junction transistors (BJTs) used in the EOS FET triggering circuit;

FIGS. 4a and 4b illustrate FETs used in the EOS FET triggering circuit;

FIG. 5 illustrates a p-channel FET configured to trigger the EOS FET, which is an n-channel FET;

FIGS. 6a-6c illustrate a voltage-limiting circuit coupled to the EOS FET gate terminal;

FIGS. 7a-7c illustrate bi-directional protection circuits utilizing EOS FETS;

FIGS. 8a and 8b illustrates an EOS FET triggering circuit utilizing a current mirror to amplify the control voltage;

FIGS. 9a and 9b illustrate a resistor in series with the EOS FET; and

FIG. 10 illustrates the EOS FET coupled to the power input of an electrical device.

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, those skilled in the art will appreciate that the description is intended to cover alternatives, modifications, and equivalents as may be included within the spirit and scope of the invention as defined by the appended claims and the claims' equivalents as supported by the following disclosure and drawings.

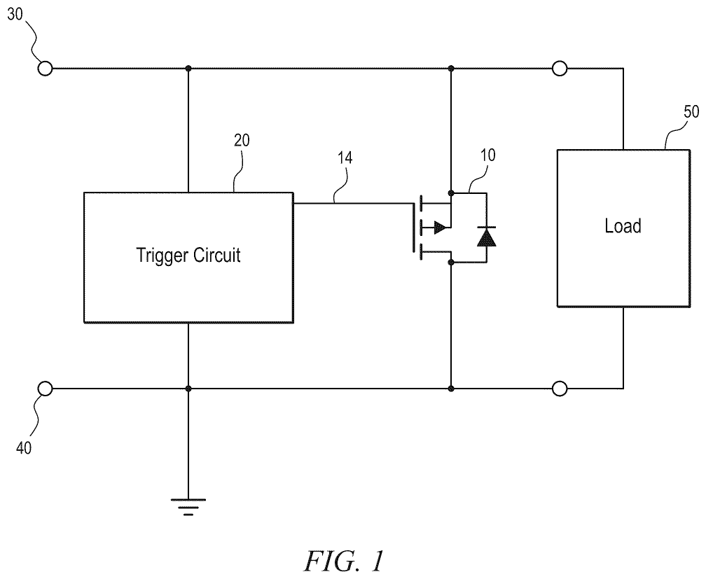

FIG. 1 illustrates a FET based electrical over-stress (EOS) suppression device. While EOS is specifically discussed, the FET based suppression device can be used to protect a load from other types of unwanted electrical transients. In FIG. 1, EOS FET 10 includes a source terminal coupled to input voltage (V_{IN}) node 30 and a drain terminal coupled to ground node 40. A gate terminal 14 of EOS FET 10 is coupled to a triggering circuit 20. Triggering circuit 20 is coupled between V_{IN} node 30 and ground node 40 in parallel with EOS FET 10. Triggering circuit 20 controls EOS FET 10 similar to an on-off switch, switching electrical current from V_{IN} node 30 to ground node 40 through the EOS FET on or off using an output coupled to gate terminal 14.

A load 50 to be protected is coupled between V_{IN} node 30 and ground node 40 in parallel with EOS FET 10. During normal operation, EOS FET 10 is off and no significant electrical current flows through the EOS FET from V_{IN} node 30 to ground node 40. Current flows from V_{IN} node 30 to ground node 40 through load 50 to power the load. When an electrical transient on V_{IN} node 30 is detected by triggering circuit 20, the triggering circuit turns on EOS FET 10 to route excess energy on V_{IN} node 30 to ground node 40. Turning on EOS FET 10 routes electrical current through the EOS FET rather than through load 50, thus keeping V_{IN} node 30 at safe voltage potentials for the load. When the transient on V_{IN} node 30 subsides, triggering circuit 20 turns EOS FET 10 back off, and the load continues being powered by the voltage potential of the V_{IN} node as normal.

One advantage of a FET based protection circuit is that the EOS FET topology does not have a latch-up mechanism. The prior art commonly uses circuits such as a TRIAC or SCR, that latch up and continue conducting current until the input voltage is completely removed. However, triggering circuit 20 is able to turn EOS FET 10 off when V_{IN} node 30 returns to a normal voltage potential, even if the input voltage does not return to zero. Another advantage is the deep snap back offered by EOS FET 10. EOS FET 10 has a low on-state voltage, thus dissipating more power for a given die size. While EOS FET 10 is illustrated as a p-channel FET, n-channel FETs can be used as well.

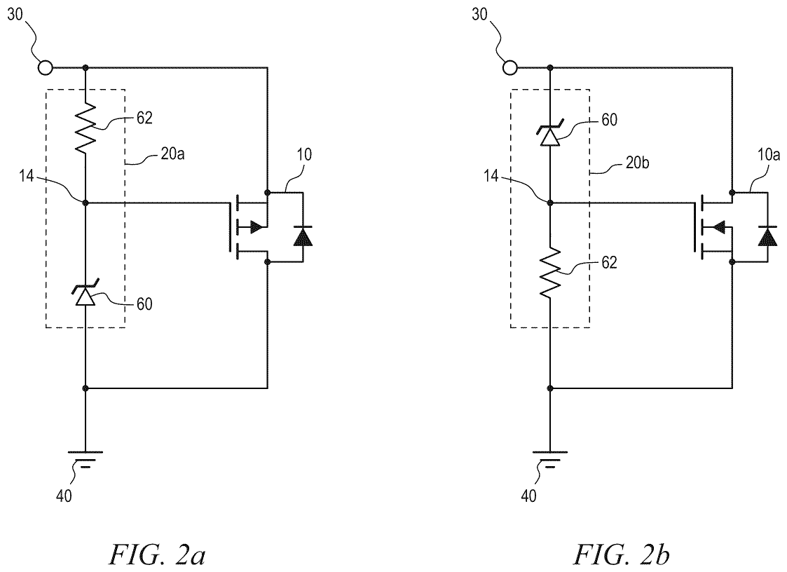

FIGS. 2a and 2b illustrate triggering circuit 20 formed using a trigger diode 60 and a resistor 62 coupled in series between V_{IN} node 30 and ground node 40. Trigger diode 60 can be any form of trigger diode, such as a TVS diode, Zener diode, or another device that contains single or multiple p-n junctions. Trigger diode 60 can be any circuit element that is approximately open circuit below a given voltage potential of V_{IN} node 30 and conducts electricity when V_{IN} node 30 exceeds the given voltage. Trigger diode 60 is selected to have a breakdown voltage (V_{BR}) equal to or greater than the expected voltage potential input to load 50.

FIG. 2a uses triggering circuit 20a to trigger a p-channel EOS FET 10. Triggering circuit 20a includes resistor 62 coupled between V_{IN} node 30 and gate 14 of EOS FET 10. Trigger diode 60 includes a cathode coupled to gate 14 and an anode coupled to ground node 40. Trigger diode 60 and resistor 62 are coupled in series between V_{IN} node 30 and ground node 40, and gate 14 of EOS FET 10 is coupled to the circuit node between the trigger diode and resistor.

During normal operation, resistor 62 couples gate 14 to V_{IN} node 30, keeping the gate of EOS FET 10 at approximately the voltage potential of V_{IN} node 30. The source terminal of EOS FET 10 is coupled to V_{IN} node 30, so the gate-to-source voltage is approximately zero and EOS FET remains off. When the voltage potential of V_{IN} node 30 exceeds the V_{BR} of trigger diode 60, electrical current flows through the trigger diode, and therefore resistor 62. The resulting voltage drop across resistor 62 lowers the voltage potential at gate terminal 14 of EOS FET 10, which causes the source-to-gate voltage to exceed the turn-on threshold of the EOS FET. EOS FET 10 is turned on, which shunts EOS current from V_{IN} node 30 to ground node 40. While some electrical current continues to flow through resistor 62 and trigger diode 60, a large majority of the transient electrical current being shunted to ground node 40 is through EOS FET 10. Trigger diode 60 can be made relatively small because electrical current through the trigger diode is orders of magnitude smaller than the overall surge current.

FIG. 2b illustrates a similar circuit utilizing triggering circuit 20b to trigger a n-channel EOS FET 10a. Triggering circuit 20b has the cathode of trigger diode 60 coupled to V_{IN} node 30 and the anode of the trigger diode coupled to gate 14. Resistor 62 is coupled between gate 14 and ground node 40. The positions of resistor 62 and trigger diode 60 are switched between triggering circuits 20a and 20b.

Triggering circuit 20b operates similarly to triggering circuit 20a. During normal operation, resistor 62 couples gate 14 to ground node 40, and keeps the gate terminal at approximately the voltage potential of ground node 40. When the input voltage potential at V_{IN} node 30 exceeds the V_{BR} Of trigger diode 60, electrical current flows through trigger diode 60 and resistor 62 in series from the V_{IN} node to ground node 40. The resultant voltage drop across resistor 62 raises the voltage potential at gate 14 of EOS FET 10a, thus turning on the EOS FET. Transient energy spikes on V_{IN} node 30 are diverted to ground node 40 through EOS FET 10a, as in FIG. 2a. In both FIGS. 2a and 2b, trigger diode 60 substantially stops conducting electrical current when the transient event subsides, and the circuit returns to the normal operating state with EOS FET 10 or 10a turned off.

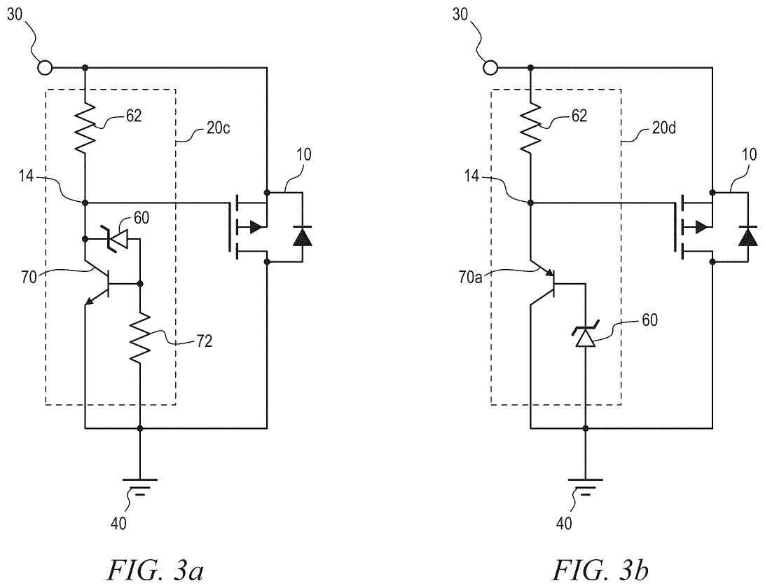

FIGS. 3a and 3b illustrate embodiments using bipolar junction transistors (BJTs) in the triggering circuit. Trigging circuit 20c in FIG. 3a is similar to triggering circuit 20a in FIG. 2a with BJT 70 and resistor 72 added. BJT 70 is an NPN BJT with a collector terminal coupled to the cathode of trigger diode 60, a base terminal coupled to the anode terminal of the trigger diode, and an emitter terminal coupled to ground node 40. Resistor 72 is coupled from the base of BJT 70 to ground node 40.

In one mode of operation, triggering circuit 20c with BJT 70 operates similarly to triggering circuit 20a in FIG. 2a. Resistor 62, resistor 72, and trigger diode 60 are coupled in series between V_{IN} node 30 and ground node 40. Resistor 62, trigger diode 60, and the base-to-emitter junction of BJT 70 are also coupled in series between V_{IN} node 30 and ground node 40. When the voltage potential of V_{IN} node 30 rises and exceeds the V_{BR} of trigger diode 60 plus the base-to-emitter voltage (V_{BE}) of BJT 70, enough biasing current flows into the base of BJT 70 to turn on the BJT. The collector of BJT 70, which is connected to V_{IN} node 30 through resistor 62, clamps at the voltage of the BJT V_{BE} plus the V_{BR} of trigger diode 60. Once current through resistor 62 causes a sufficient voltage drop at gate 14, EOS FET 10 turns on to divert surge current primarily through the EOS FET rather than BJT 70. Resistor 72 is a bleeding resistor that helps bypass some current through trigger diode 60 to ground node 40 instead of into the base of BJT 70. Resistor 72 helps reduce the likelihood of BJT 70 turning on undesirably under high temperature conditions.

In a second mode of operation, BJT 70 has the added benefit of reducing the response time of the triggering circuit during high slew rate transients. When the voltage potential of V_{IN} node 30 rises at a sufficiently high rate, electrical current through a parasitic capacitance of BJT 70 is able to raise the voltage potential at the base of the BJT. The current through the parasitic capacitance of BJT 70 is able to turn on the BJT prior to the input voltage reaching the breakdown voltage of trigger diode 60 plus the V_{BE} of BJT 70 during a transient event with a sufficiently fast rise time. Because BJT 70 turns on EOS FET 10 at a lower voltage than the V_{BR} of trigger diode 60 plus V_{BE} Of BJT 70 by being slew rate triggered, the clamping voltage across the circuit, and thus power dissipation in the EOS FET, is reduced. A triggering circuit with BJT 70 can handle even higher peak pulse currents at the same FET size due to the reduced clamping voltage. Another advantage is that BJT 70 helps sink some of the transient current to ground in addition to allowing transients to be shunted to ground sooner.

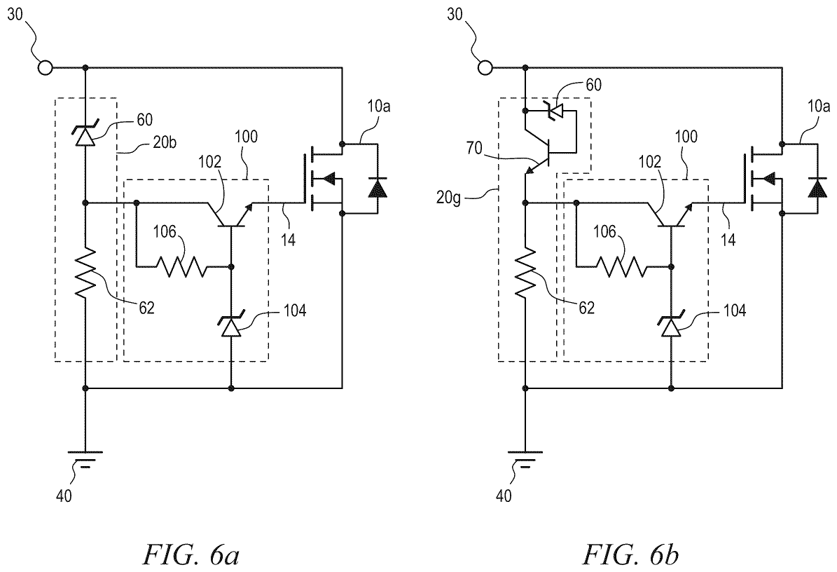

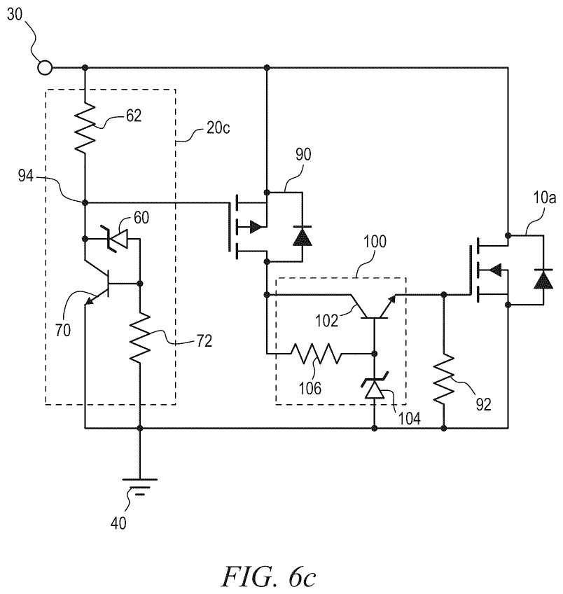

FIG. 3b illustrates a similar circuit with a PNP BJT 70a. BJT 70a includes an emitter terminal coupled to V_{IN} node 30 through resistor 62, a base terminal coupled to the cathode of trigger diode 60, and a collector terminal coupled to ground node 40. The anode of trigger diode 60 is coupled to ground node 40. Gate 14 of EOS FET 10 is coupled to a circuit node between BJT 70a and resistor 62. When the input voltage exceeds the sum of the base-to-emitter turn-on voltage of BJT 70a and the V_{BR} of trigger diode 60, current flows through resistor 62 and the voltage drop across the resistor turns on EOS FET 10. As above in FIG. 3a, electrical current through the parasitic capacitor of BJT 70a during high slew-rate transient events is capable of turning on the BJT prior to V_{IN} node 30 reaching the V_{BR} of trigger diode 60. While a p-channel EOS FET 10 is used in FIGS. 3a and 3b, similar circuits could be made using either an NPN or PNP BJT and n-channel EOS FET 10a. One example is illustrated in FIG. 6b below.

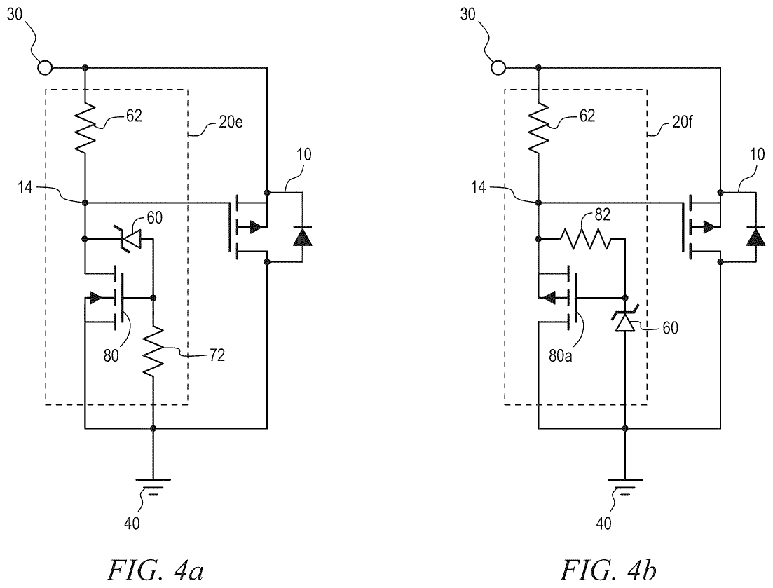

FIGS. 4a and 4b illustrate similar circuits to those in FIGS. 3a and 3b, but with BJTs 70 and 70a replaced by FET devices 80 and 80a, respectively. Triggering circuits 20e and 20f in FIGS. 4a and 4b operate similarly, and provide similar benefits, to triggering circuits 20c and 20d in FIGS. 3a and 3b. Triggering circuit 20f adds a resistor 82 to create a control voltage at the gate terminal of FET 80a, which was not necessary in triggering circuit 20d because BJT 70a is controlled by an electrical current.

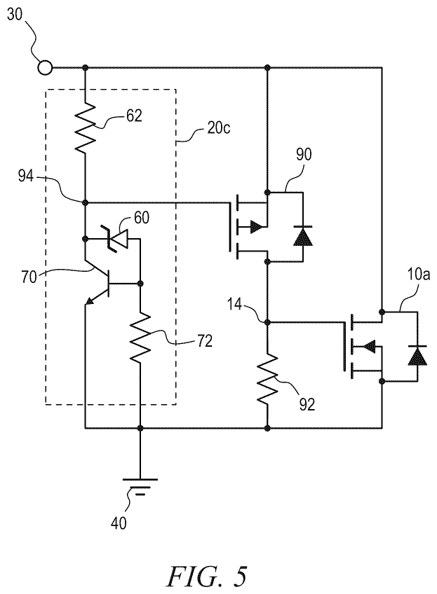

FIG. 5 illustrates an embodiment with the main path for conducting transient current being n-channel EOS FET 10a. A p-channel FET 90 is used to drive EOS FET 10a. Gate 94 of FET 90 is coupled to a circuit node between BJT 70 and resistor 62. Triggering circuit 20c in FIG. 5 is the same as in FIG. 3a, but any of the above or below described triggering circuits can be used with FET 90 between the triggering circuit and the EOS FET as a driver. When the input voltage on V_{IN} node 30 exceeds the threshold for triggering circuit 20c turning on FET 90, current flows through resistor 92. The current through resistor 92 raises the voltage at gate 14 of EOS FET 10a, thus turning on the EOS FET and diverting transient current to ground through the main EOS FET.

An n-channel FET, as used for EOS FET 10a in FIG. 5, is desirable because an n-channel FET is normally smaller than a p-channel FET for a given current sinking capability. However, the n-channel EOS FET 10a requires a positive gate to source voltage to turn on. Having n-channel EOS FET 10a triggered by p-channel FET 90 allows the EOS FET to be triggered by a negative gate-to-source control signal from triggering circuit 20c using FET 90 as a driver. In other embodiments, an n-channel FET 90 is used to drive a p-channel EOS FET 10.

FIGS. 6a-6c illustrate a voltage-limiting circuit 100 coupled between triggering circuit 20 and EOS FET 10a. FIG. 6a illustrates the embodiment of FIG. 2b with the addition of a voltage-limiting circuit 100 coupled between triggering circuit 20b and EOS FET 10a. Voltage-limiting circuit 100 includes BJT 102, diode 104, and resistor 106. Diode 104 is a Zener diode or another type of diode with a predictable V_{BR}. As with FIG. 2b, EOS FET 10a is turned on when V_{IN} node 30 exceeds the V_{BR} of trigger diode 60. Resistor 106 routes electrical current from V_{IN} node 30 to the base terminal of BJT 102 to forward bias the base-emitter junction and allow current to flow from the V_{IN} node to the gate of EOS FET 10a. In FIG. 2a, the voltage potential at gate terminal 14 increases indefinitely with increasing voltage of V_{IN} node 30. In FIG. 6a, voltage-limiting circuit 100 limits the voltage at gate terminal 14. When the voltage potential at gate 14 exceeds the V_{BR} of diode 104, electrical current from V_{IN} node 30 through trigger diode 60 flows through resistor 106 and diode 104 to ground node 40 rather than only through resistor 62 to further increase the voltage at gate 14.

FIG. 6b illustrates voltage-limiting circuit 100 applied to a variation of the triggering mechanism in FIGS. 3a and 3b having an n-channel EOS FET 10a and an NPN BJT 70. In triggering circuit 20g of FIG. 6b, BJT 70 is coupled between V_{IN} node 30 and gate 14 to account for the n-channel FET, as opposed to triggering circuit 20c where BJT 70 is between the gate and ground node 40.

FIG. 6c illustrates voltage-limiting circuit 100 applied to the embodiment of FIG. 5 with triggering circuit 20c and driver FET 90. BJT 102, diode 104, and resistor 106 in FIGS. 6b and 6c limit the voltage potential at the gate terminal of EOS FET 10a in a similar manner as in FIG. 6a. A similar voltage-limiting circuit can be used with any of the above or below described triggering circuits, with any of the triggering circuit 20 embodiments, and with or without driver FET 90.

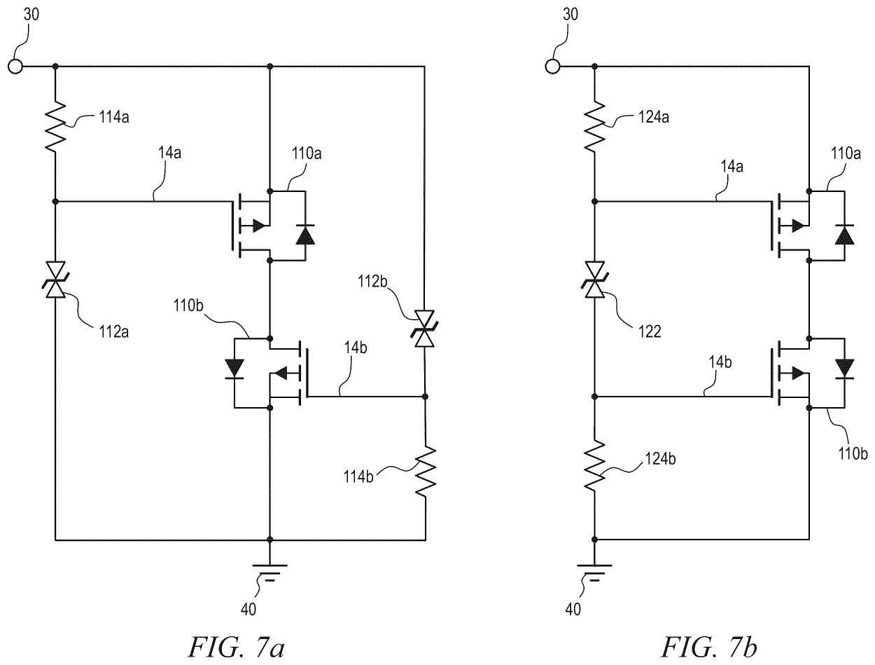

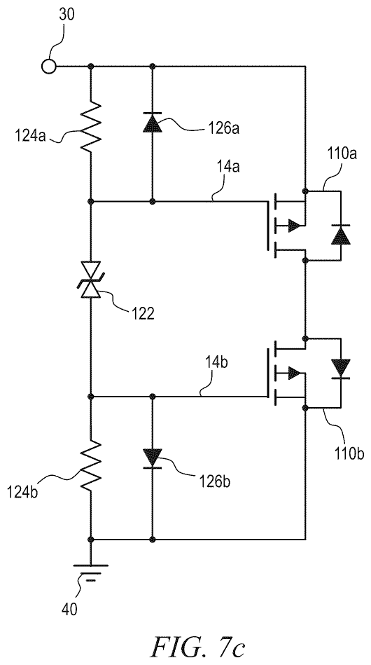

A bidirectional transient suppression circuit, i.e., able to conduct transient surges with either positive or negative polarity, can be made by combining any two of the above or below described unidirectional transient voltage suppression circuits in a back-to-back configuration. FIGS. 7a-7c illustrate additional bi-directional embodiments formed using bi-directional trigger diodes along with two p-channel EOS FETs.

In FIG. 7a, EOS FETs 110a and 110b are coupled in series between V_{IN} node 30 and ground node 40. Both EOS FETs 110a and 110b are p-channel FETs. Trigger diodes 112a and 112b are bi-directional trigger diodes. Trigger diodes 112a and 112b conduct electrical current if the voltage potential at V_{IN} node 30 exceeds ground node 40 by at least the breakdown voltage of the trigger diodes, or if the V_{IN} node is below ground by the breakdown voltage or more. When trigger diodes 112a and 112b conduct with a positive input voltage at V_{IN} node 30, electrical current through resistor 114a creates a voltage across the resistor that turns on EOS FET 110a. The transient current flows through EOS FET 110a and the body diode of EOS FET 110b to ground node 40. Even though electrical current through resistor 114b raises the voltage potential at gate 14b, keeping EOS FET 110b turned off, the transient current is able to flow through EOS FET 110b via the body diode.

When trigger diodes 112a and 112b conduct a transient having a negative voltage potential on V_{IN} node 30, current through resistor 114b turns on EOS FET 110b allowing the transient current to flow through EOS FET 110b and the body diode of EOS FET 110a. With either positive or negative transients on V_{IN} node 30, transient current flows primarily through EOS FETs 110a and 110b.

FIG. 7b illustrates another bi-directional embodiment with trigger diode 122 and resistors 124a and 124b coupled in series between V_{IN} node 30 and ground node 40. Trigger diode 122 is coupled to V_{IN} node 30 through resistor 124a and ground node 40 through resistor 124b. EOS FETs 110a and 110b are both p-channel devices and coupled in series with each other between V_{IN} node 30 and ground node 40 in parallel with diode 122, resistor 124a, and resistor 124b. Gate 14a of EOS FET 110a is coupled between resistor 124a and trigger diode 122. Gate 14b of EOS FET 110b is coupled between resistor 124b and trigger diode 122. Current flows through trigger diode 122 when the voltage potential of V_{IN} node 30 exceeds the V_{BR} of the trigger diode in either the positive or the negative direction relative to ground node 40. Electrical current through resistor 124a from V_{IN} node 30 during positive transients turns on EOS FET 110a, and transient current is shunted to ground node 40 through EOS FET 110a and the body diode of EOS FET 110b. Electrical current through resistor 124b from ground node 40 during negative transients on V_{IN} node 30 turns on EOS FET 110b, and the negative transient current is shunted to ground through EOS FET 110b and the body diode of EOS FET 110a.

FIG. 7c illustrates an embodiment with optional diodes 126a and 126b added to the embodiment of FIG. 7b. Diodes 126a and 126b help by limiting the voltage drop across resistors 124a and 124b, respectively, when the voltage across the respective resistor 124 is not being relied on to turn on a respective EOS FET 110. Diodes 126a and 126b limit the voltage potential of gates 14a and 14b in the direction that turns off the respective EOS FET 110.

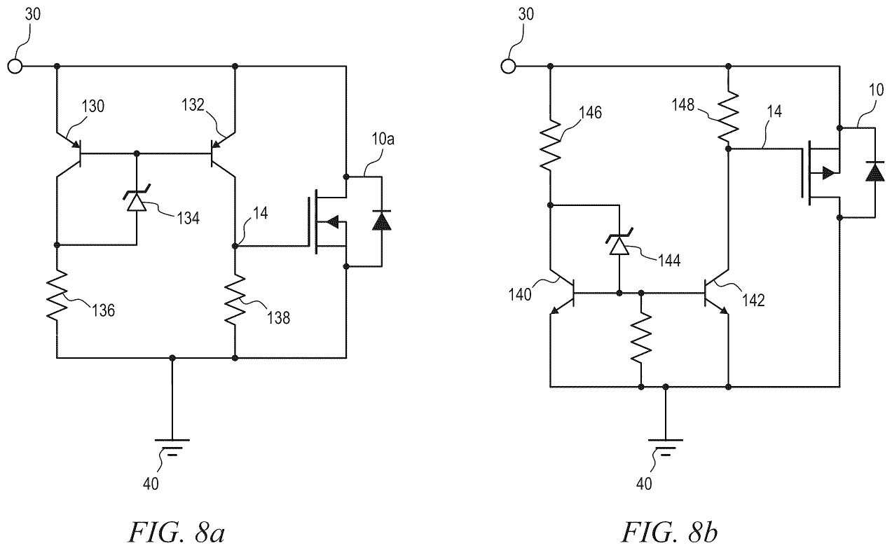

FIGS. 8a and 8b illustrate embodiments with a current mirror used to amplify the gate voltage applied to an EOS FET. FIG. 8a shows n-channel EOS FET 10a coupled between V_{IN} node 30 and ground node 40. PNP BJTs 130 and 132 both have emitters coupled to V_{IN} node 30. The base terminals of BJTs 130 and 132 are coupled to each other and a cathode of trigger diode 134. The collector of BJT 130 is coupled to ground node 40 through resistor 136. The collector of BJT 132 is coupled to ground node 40 through resistor 138. Gate 14 of EOS FET 10a is coupled between BJT 132 and resistor 138.

A current mirror works by having the emitters and bases of both BJTs 130 and 132 held at approximately the same voltage potential. The voltage potential of V_{IN} node 30 at which the BJTs are turned on is controlled by the V_{BR} of trigger diode 134. Once BJTs 130 and 132 are turned on, the ratio of current through the BJTs is controlled by the ratio of the values of resistors 136 and 138.

When input voltage at V_{IN} node 30 is less than the V_{BR} of trigger diode 134, BJTs 130 and 132 do not conduct significant current, and no significant current flows through resistor 138. The gate of EOS FET 10a is at approximately ground potential. When the input voltage increases sufficiently to cause trigger diode 134 to conduct, BJTs 130 and 132 turn on and conduct current. Electrical current through BJT 132 is amplified by configuration of the current mirror ratio, causing the voltage drop across resistor 138 to be a larger magnitude than the voltage drop across resistor 136. The amplification causes the voltage at gate 14 to reach the turn-on threshold of EOS FET 10a in circumstances when the circuit might not otherwise be able to turn on the EOS FET. A current mirror could also be implemented with PNP BJTs instead of the illustrated NPN BJTs, or p-channel or n-channel FETs.

FIG. 8b illustrates a similar embodiment with p-channel EOS FET 10. Similar to FIG. 8a, when V_{IN} node 30 exceeds the V_{BR} of trigger diode 144, current through BJT 140 and resistor 146 is amplified through BJT 142 to a larger voltage drop across resistor 148. The voltage drop across resistor 148 exceeds the turn-on threshold of EOS FET 10, and the surge current is shunted to ground through the EOS FET.

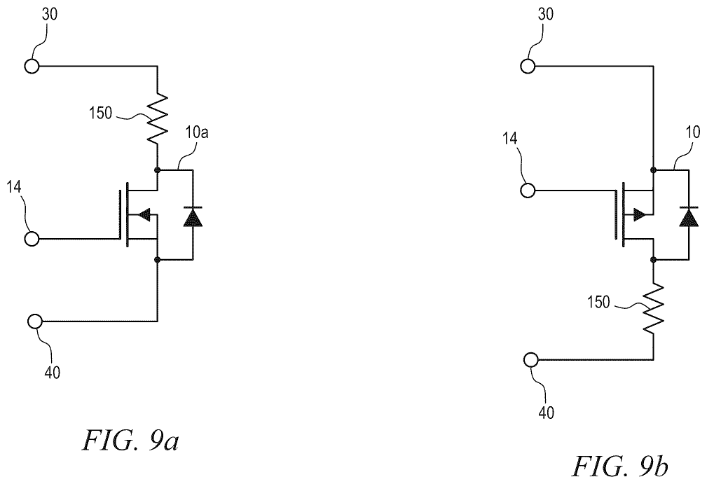

FIGS. 9a and 9b illustrate an optional resistor 150 coupled in series with the EOS FETs in any of the above embodiments. Resistor 150 shares the voltage stress with the EOS FET, which improves the amount of surge current the EOS FET is capable of handling. Resistor 150 is coupled on the drain side of either the n-channel EOS FET 10a or the p-channel EOS FET 10 so that the voltage drop across the resistor does not change the gate-to-source voltage. However, resistor 150 could be placed on the source side of the EOS FET in other embodiments. In the bi-directional embodiments in FIGS. 7a-7c, resistor 150 can be coupled between the two EOS FETs 110a and 110b so that the resistor is on the drain side of both EOS FETs.

The protection circuits disclosed above replace the physically large high-voltage and high-current TVS diode, used in the prior art to shunt transients, with a much smaller high-voltage TVS diode that is used to trigger an EOS FET. The EOS FET is the primary current path for unwanted transient current. A bipolar transistor could be used instead of the EOS FET.

However, FETs are preferable because voltage is used to control the FET, which has a high impedance for the control circuitry. Getting a sufficient base current for an EOS BJT is more challenging than simply raising a FET's gate to a sufficient voltage potential.

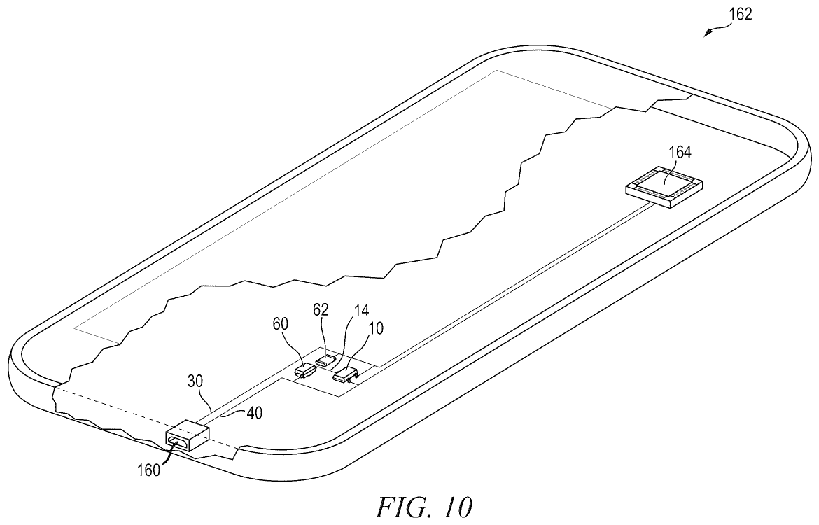

FIG. 10 illustrates mobile device 162 with EOS FET 10 coupled between the power and ground conductive traces from a Universal Serial Bus (USB) port 160. The power and ground of USB port 160 are coupled to V_{IN} node 30 and ground node 40, respectively, within mobile device 162. V_{IN} node 30 and ground node 40 are routed to a mobile system-on-chip (SoC) processor 164 to power the SoC. EOS FET 10 is coupled between V_{IN} node 30 and ground node 40 to absorb transient electrical events on the power input. Trigger diode 60 and resistor 62 are provided to turn on EOS FET 10 during transient events. EOS FET 10 provides protection to any connected components of mobile device 162.

Any of the other disclosed triggering mechanism and EOS FET embodiments are used in other embodiments. The disclosed EOS FET circuits can be used to shunt transients to ground in any other suitable electronic device besides mobile device 162. The EOS FET protection circuits can also be used to protect any device coupled to any electrical signal, not just a low voltage power signal, e.g., higher voltage buses, audio signals, data signals, etc.

While one or more embodiments of the present invention have been illustrated in detail, the skilled artisan will appreciate that modifications and adaptations to those embodiments may be made without departing from the scope of the present invention as set forth in the following claims.

What is claimed:

1. A semiconductor device, comprising:
a first circuit node;
a second circuit node;
a first transistor coupled between the first circuit node and second circuit node;
a second transistor coupled between the first circuit node and a control terminal of the first transistor;
a triggering circuit coupled between the first circuit node, the second circuit node, and a control terminal of the second transistor; and
a voltage limiting circuit coupled between the second transistor and the control terminal of the first transistor, wherein the voltage limiting circuit includes a third transistor comprising a first conduction terminal of the third transistor coupled to a first conduction terminal of the second transistor and a second conduction terminal of the third transistor coupled to the control terminal of the first transistor, and wherein the second transistor is configured as a driver for the first transistor.

2. The semiconductor device of claim 1, wherein the triggering circuit includes a Zener diode.

3. The semiconductor device of claim 2, wherein the triggering circuit further includes a fourth transistor comprising a control terminal of the fourth transistor coupled to the Zener diode.

4. The semiconductor device of claim 1, wherein the voltage limiting circuit includes a Zener diode coupled to a control terminal of the third transistor.

5. The semiconductor device of claim 4, wherein the Zener diode is coupled between the second circuit node and the control terminal of the third transistor.

6. The semiconductor device of claim 1, further including a resistance coupled between the first circuit node and second circuit node in series with the first transistor.

7. A semiconductor device, comprising:
a first circuit node;
a second circuit node;
a first transistor coupled between the first circuit node and second circuit node;
a second transistor coupled between the first circuit node and a control terminal of the first transistor;
a triggering circuit coupled between the first circuit node, the second circuit node, and a control terminal of the second transistor; and
a voltage limiting circuit coupled between the second transistor and the control terminal of the first transistor, wherein the voltage limiting circuit includes a Zener diode.

8. The semiconductor device of claim 7, wherein the second transistor is configured as a driver for the first transistor through the voltage limiting circuit.

9. The semiconductor device of claim 7, wherein the voltage limiting circuit includes a third transistor comprising a first conduction terminal of the third transistor coupled to a first conduction terminal of the second transistor, a second conduction terminal of the third transistor coupled to the control terminal of the first transistor, and a control terminal of the third transistor coupled to the Zener diode.

10. The semiconductor device of claim 7, further including a resistance coupled between the first circuit node and second circuit node in series with the first transistor.

11. The semiconductor device of claim 7, further including a load including a first terminal of the load coupled directly to the first circuit node and a second terminal of the load coupled directly to the second circuit node.

12. The semiconductor device of claim 7, wherein the triggering circuit includes a second Zener diode.

13. The semiconductor device of claim 12, wherein the triggering circuit further includes a fourth transistor comprising a control terminal of the fourth transistor coupled to the second Zener diode.

14. A method of electrical-overstress protection, comprising:
coupling a first transistor between a first circuit node and second circuit node;
coupling a second transistor between the first circuit node and a control terminal of the first transistor;
coupling a triggering circuit between the first circuit node, the second circuit node, and a control terminal of the second transistor; and
coupling a voltage limiting circuit between the second transistor and the control terminal of the first transistor, wherein the voltage limiting circuit includes a Zener diode.

15. The method of claim 14, further including configuring the second transistor to drive the first transistor through the voltage limiting circuit.

16. The method of claim 14, wherein the voltage limiting circuit includes a third transistor comprising a first conduction terminal of the third transistor coupled to a first conduction terminal of the second transistor, a second conduction terminal of the third transistor coupled to the control terminal of the first transistor, and a control terminal of the third transistor coupled to the Zener diode.

17. The method of claim 14, further including coupling a resistance between the first circuit node and second circuit node in series with the first transistor.

18. The method of claim 14, further including disposing a load with a first terminal of the load coupled directly to the first circuit node and a second terminal of the load coupled directly to the second circuit node.

19. The method of claim 14, further including providing the triggering circuit to include a second Zener diode.

20. The method of claim 19, further including providing the triggering circuit to include a fourth transistor comprising a control terminal of the fourth transistor coupled to the second Zener diode.
